(19) United States
(12) Patent Application Publication
(10) Pub. No.: US 2010/0056036 A1
(43) Pub. Date: Mar. 4, 2010

(54) NOISE-REDUCING SIDE CHAMBERS FOR AIR EXHAUST FROM COMPUTER RACKS AND A METHOD OF EXHAUSTING AIR AND REDUCING NOISE BY USING THE SAME

(75) Inventor: Matthew A. NOBILE, Poughkeepsie, NY (US)

Correspondence Address: McGinn Intellectual Property Law Group, PLLC, 8321 Old Courthouse Road, Suite 200, Vienna, VA, 22182-3817, US

(73) Assignee: INTERNATIONAL BUSINESS MACHINES CORPORATION, Armonk, NY (US)

(21) Appl. No.: 12/203,680

(22) Filed: Sep. 3, 2008

(51) Int. Cl. H05K 5/02

(52) U.S. Cl. 454/184

(57) ABSTRACT

A method of exhausting exhaust air and reducing exhaust-air associated noise from a computer rack includes exhausting the exhaust air and the exhaust-air associated noise from a rear-mounted blower directly through a side opening at a rear portion of the computer rack, channeling the exhaust air and the exhaust-air associated noise through an acoustically absorptive side chamber, the acoustically absorptive side chamber sealed to the side opening of the computer rack such that the exhaust air and the exhaust-air associated noise is ducted through the acoustically absorptive side chamber and exits the acoustically absorptive side chamber at an upper portion of the acoustically absorptive side chamber in a vertical direction towards a ceiling of a data center in which the computer rack is installed, and using an acoustically absorptive duct of the acoustically absorptive side chamber to significantly attenuate the exhaust-air associated noise prior to radiating the exhaust-air associated noise from the upper portion of the acoustically absorptive side chamber.

### BACKGROUND OF THE INVENTION

1. Field of the Invention

The present invention generally relates to noise-reducing side chambers for air exhaust from computer racks, and, more specifically, to noise-reducing side chambers for air exhaust from computer racks that provide a solution to the drawbacks of systems that exhaust air at a rear portion of a rack of a conventional high-end server.

2. Description of the Related Art

FIGS. 1 and 2 illustrate a perspective and a plan view, respectively, of a conventional server design where air exhausts from several large air moving devices 2, i.e. blowers, at a rear portion 3 of a rack 4. These large air moving devices 2 draw air through a front portion 5 of the rack 4 and exhaust the air through the rear portion 3 of the rack 4.

The conventional server 1 requires very high volumes of air to be drawn and exhausted in order to cool electronic components in the server. This results in very high volumes of relatively hot air exhausting directly out of the rear portion 3 of the rack 4. Commonly referred to as a “hot air in the face” problem, this condition has a generally negative impact on customer satisfaction. More importantly, this also poses a significant problem during servicing of the conventional server 1, due to the necessary performance by those servicing the unit of delicate and complicated operations at the rear portion 3 of the rack 4.

Further, since a significant amount of acoustical noise is generated at outlets of the large air moving devices 2, the rear portion 3 of the rack 4 is excessively noisy. In fact, the noise from outlets of the large air moving devices 2 is often so high that it is damaging to hearing unless hearing protectors are worn.

To reduce the noise, special acoustical doors 11 are sometimes attached to the rear portion 3 of the rack 4, as is shown in FIG. 2. However, this design causes an increase in flow impedance and negatively affects thermal performance of the conventional server 1. Further, these acoustical doors 11 need to be relatively deep to be effective. This sometimes adversely affects a data center layout and aisle width. In addition, when opening the acoustical doors 11 to service the conventional server 1, one is exposed to damagingly high levels of acoustical noise. Thus, hearing protectors are needed while servicing the conventional server 1. This, in turn, makes communication with others during servicing to be very problematic if not impossible. Furthermore, when the doors 11 are opened for servicing, the very high volumes of air at the rear 3 of the rack 4 interfere with the delicate and complicated operations that must be performed by service technicians.

Moreover, since the air must exhaust through the rear portion 3 of the rack 4 in the conventional server 1, opening and closing the rear portion 3 affects the flow impedance seen by the large air moving devices 2 and a thermal operating point of the conventional server 1. This is especially true when the rear portion 3 includes the acoustical doors 11. In order to be effective from a noise reduction standpoint, the acoustical doors 11 cannot have significantly large openings. Thus, there are rather large deviations in the thermal design point of the server 1 when the acoustical doors 11 are opened and closed.

Also, conventional servers 1 are “brick walled” side to side together in long strings in the data center. Exhausting air through the rear portion 3 of the rack 4 of the conventional server 1 does not make the “brick walled” setup particularly advantageous. In order to manage skyrocketing energy requirements, spaced racks are being implemented in the conventional server 1 to reduce energy density. Nevertheless, when the conventional server 1 includes racks that are simply spaced apart, hot air recirculation occurs around the sides of the racks, from the hot aisle into the cold aisle, defeating the purpose of spacing apart the racks in the first place.

### SUMMARY OF THE INVENTION

In view of the foregoing and other exemplary problems, drawbacks, and disadvantages of the conventional methods and structures, an exemplary object of the present invention is to provide an air exhaust solution for a high-end server unit that overcomes the documented drawbacks of the rear air exhaust solution of a conventional high-end server.

An exemplary embodiment of the present invention includes a method of exhausting exhaust air and reducing exhaust-air associated noise from a computer rack, including exhausting the exhaust air from a rear-mounted blower directly through a side opening at a rear portion of the computer rack, channeling the exhaust air and the exhaust-air associated noise through an acoustically absorptive side chamber, the acoustically absorptive side chamber sealed to the side opening of the computer rack such that the exhaust air and the exhaust-air associated noise is ducted through the acoustically absorptive side chamber and exits the acoustically absorptive side chamber at an upper portion of the acoustically absorptive side chamber in a vertical direction towards a ceiling of a data center in which the computer rack is installed, and using an acoustically absorptive duct of the acoustically absorptive side chamber to significantly attenuate the exhaust-air associated noise prior to radiating the exhaust-air associated noise from the upper portion of the acoustically absorptive side chamber.

The exhaust air and the exhaust-air associated noise are prevented from exhausting through a rear portion of the computer rack. The rear portion of the computer rack includes a decorative rear door designed to have a minimal impact on floor space and aisle space of the data center, the decorative rear door being able to be opened without the exhaust air and exhaust-air associated noise escaping through the rear portion of the computer rack, the decorative rear door including an inexpensive, thin, and lightweight material. The exhaust air exits vertically from the upper portion of the acoustically absorptive side chamber with sufficient momentum such that a plurality of computer racks of the data center are unable to intake the exhaust air. The upper portion of the acoustically absorptive side chamber includes an air exhaust opening, the air exhaust opening having a height substantially similar to that of a top of the computer rack.

Both the air and the noise are hence prevented from exhausting through a rear portion of the computer rack. A rear door of the computer rack is opened without exhaust of the air and escape of the noise through the rear portion of the computer rack. Furthermore, such a rear door may now take the form of a simple inexpensive, thin, lightweight decorative door that does not impact floorspace or constrict aisle space because there is no longer a need for the rear door to attenuate noise or to manage high volumes of air with minimum pressure drop. The air exits vertically from the upper portion of the side chamber with sufficient momentum such that a plurality of computer racks does not re-circulate the air from the upper portion of the side chamber. The air exhaust opening at the top portion of the side chamber is generally at the same height as the top of the computer rack itself, but this invention allows for an additional duct of arbitrary length to be attached to the top of the side chamber to further channel the hot exhaust air beneficially to a higher point in the room or directly to a plenum or inlet duct of the room air-conditioning system. The use of such a duct will further lower both radiated noise and hot air recirculation.

Another exemplary embodiment of the present invention includes allowing the acoustically absorptive side chambers to be detached and to restore the computer rack to the traditional rear-exhaust arrangement. In the latter instance, the side chambers are removed, the openings in the sides of the rack are sealed, and the racks may be installed or “brick walled” in the traditional manner.

These implementations greatly reduce noise levels in a data center and make it easier for service personnel to communicate with one another and perform their respective duties effectively. In addition, the aforementioned “hot air in the face” problem is eliminated. Further, the acoustically lined chambers also serve as spacers and anti-recirculation barriers between normally spaced racks. In fact, the chambers force the racks to be spaced apart, thus saving energy for data center customers.

### BRIEF DESCRIPTION OF THE DRAWINGS

The foregoing and other exemplary purposes, aspects and advantages will be better understood from the following detailed description of an exemplary embodiment of the invention with reference to the drawings, in which:

FIG. 1 illustrates a perspective view of a conventional server design where air exhausts from blowers at a rear portion of a rack;

FIG. 2 illustrates a plan view of the conventional server design where air exhausts from blowers at the rear portion of the rack;

FIG. 3 illustrates a perspective view of an exemplary embodiment of a computer rack having noise-reducing chambers of the present invention for air exhaust;

FIG. 4 illustrates a plan view of the exemplary embodiment of FIG. 3 of the computer rack having noise-reducing chambers of the present invention for air exhaust;

FIG. 5 illustrates an exemplary embodiment of a method of exhausting air and reducing noise from a computer rack using the noise-reducing side chambers of the present invention; and

FIG. 6 illustrates an exemplary embodiment of a system of exhausting air and reducing noise from a computer rack using the noise-reducing side chambers of the present invention

### DETAILED DESCRIPTION OF EXEMPLARY EMBODIMENTS OF THE INVENTION

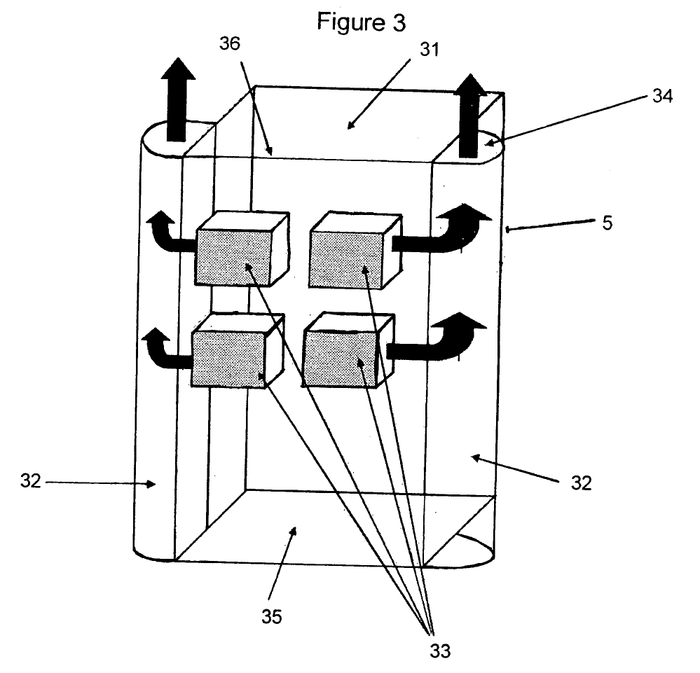

Referring now to the drawings, and more particularly to FIGS. 3-6, there are shown exemplary embodiments of the structures and method according to the present invention.

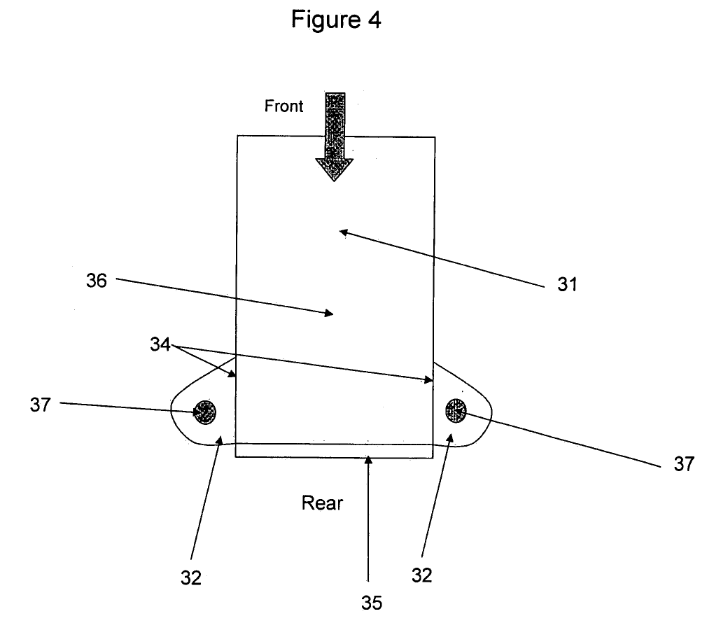

FIG. 3 illustrates a perspective view of an exemplary embodiment of a computer rack 31 for a server having noise-reducing chambers 32 of the present invention for air exhaust. FIG. 4 illustrates a plan view of the exemplary embodiment of FIG. 3 of the computer rack 31 for the server having noise-reducing chambers 32 of the present invention for air exhaust.

According to FIGS. 3 and 4, blowers 33 are provided within the rack 31 that are oriented such that air is exhausted from side portions 34 of the rack 31. Exhausting air from the side portions 34 instead of from the rear portion 35 of the rack 31 eliminates the aforementioned “hot air in the face” problem for those servicing the server through the rear portion 35. Thus, when the air is exhausted from the side portions 34 instead of from the rear portion 35 of the rack 31, servicing the rear portion 35 of the rack 31 is much easier. Also, servicing the rear portion 35 of the rack 31 does not lead to a lapse in performance of the cooling of the rack 31, because the air does not exhaust to the rear portion 35 of the rack 31.

Further according to FIGS. 3 and 4, absorptive side chambers 32 are provided on the side portions 34 of the rack 31. The absorptive side chambers 32 channel air exhausted through the side portions 34 upward such that the exhaust air exits the absorptive side chambers 32 above a footprint of the rack 31. This allows the hot air to exhaust up and above the rack 31 instead of to the rear portion 35 of the rack 31. This also prevents the hot air exhausted from the rack 31 from being simply re-circulated through an intake of other blowers installed in other racks in a data center. The upper portion of the acoustically absorptive side chambers 32 include air exhaust openings 37, the air exhaust openings 27 having a height substantially similar to that of a top of the computer rack. This promotes more efficient cooling for the data center as a whole.

Also shown in FIGS. 3 and 4, the noise generated from operation of the blowers 33 is absorbed by the absorptive side chambers 32 formed on the side portions 34 of the rack 31. These particular absorptive side chambers 32 are acoustically absorptive for the absorbing of the noise generated by the operation of the blowers 33. This promotes much quieter operation of a computer rack 31 including blowers 33.

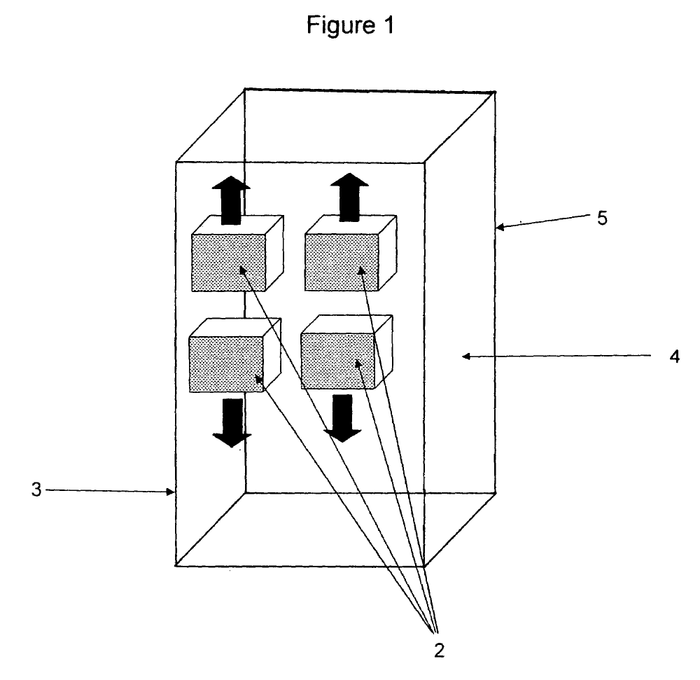

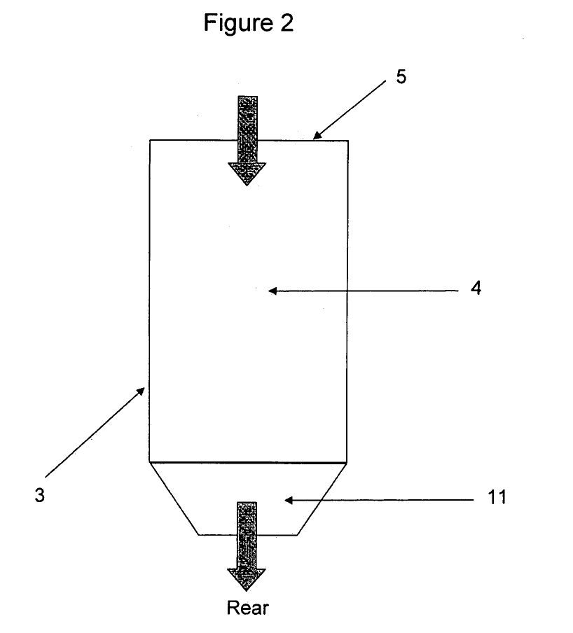

Also, there is no more need for the deep acoustical doors 11 shown in FIG. 2 of the conventional system. An inexpensive and thin material can be used for a door (not shown) provided on the rear portion 35 of the rack 31 of the exemplary embodiment of the present invention. In addition, the absorptive side chambers 32 prevent any difference in noise level or air flow when the door provided on the rear portion 35 is opened. These traits provide a computer rack 31 that is much better suited for being serviced through a rear portion 35 than the conventional computer rack 4 of FIGS. 1 and 2.

Further, in the exemplary embodiment of the present invention, noise can be radiated from a top portion 36 of the rack 31 through an upper portion 37 of the absorptive side chambers 32. This may further provide reduced noise levels in a data center.

In addition, a duct 38 may be formed on the upper portion of the absorptive side chambers 32 at the air exhaust openings 37. This duct 38 may provide a channel to exhaust the air from the absorptive side chambers 32 into a ceiling cooling environment (not shown) for a data center full of many servers having the same absorptive side chambers 32. This modification provides even more efficiency and even less noise.

Moreover, there is easy conversion to the conventional rack system to the computer rack 31, switching the exhaust back from side exhaust to rear exhaust depending on the preference of the unit. For example, blowers 33 can be configured to exhaust to one of the absorptive side chambers 32 or through the rear portion 34 of the computer rack 31, where a rear door heat exchanger (not shown) may be disposed for efficient cooling of the computer rack 31.

It is important to note that there is no specific geometric shape required of the absorptive side chambers 32. The absorptive side chambers 32 may be specifically designed to satisfy the space and design requirements of the user.

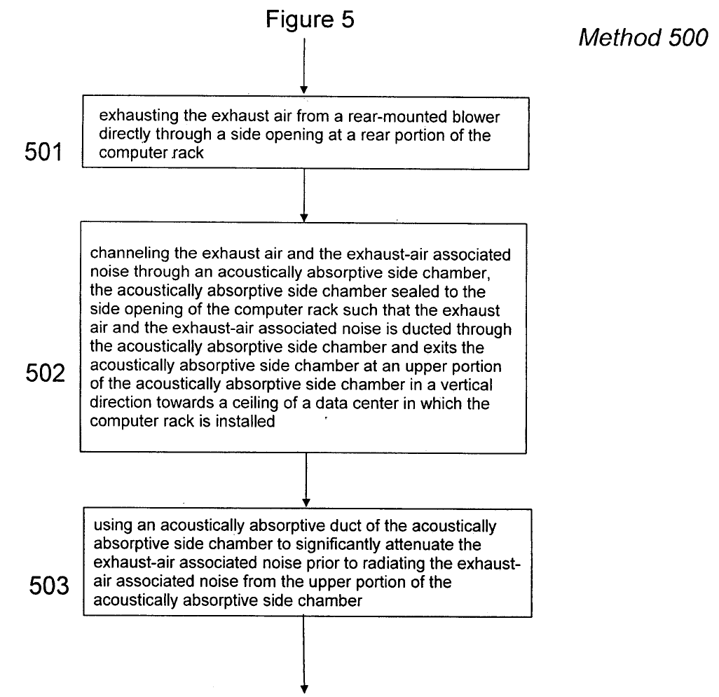

FIG. 5 illustrates an exemplary embodiment of a method 500 of exhaust air and reducing exhaust-air associated noise from a computer rack of the present invention. According to FIG. 5, the method 500 includes (501) exhausting the exhaust air from a rear-mounted blower directly through a side opening at a rear portion of the computer rack, (502) channeling the exhaust air and the exhaust-air associated noise through an acoustically absorptive side chamber, the acoustically absorptive side chamber sealed to the side opening of the computer rack such that the exhaust air and the exhaust-air associated noise is ducted through the acoustically absorptive side chamber and exits the acoustically absorptive side chamber at an upper portion of the acoustically absorptive side chamber in a vertical direction towards a ceiling of a data center in which the computer rack is installed, and (503) using an acoustically absorptive duct of the acoustically absorptive side chamber to significantly attenuate the exhaust-air associated noise prior to radiating the exhaust-air associated noise from the upper portion of the acoustically absorptive side chamber.

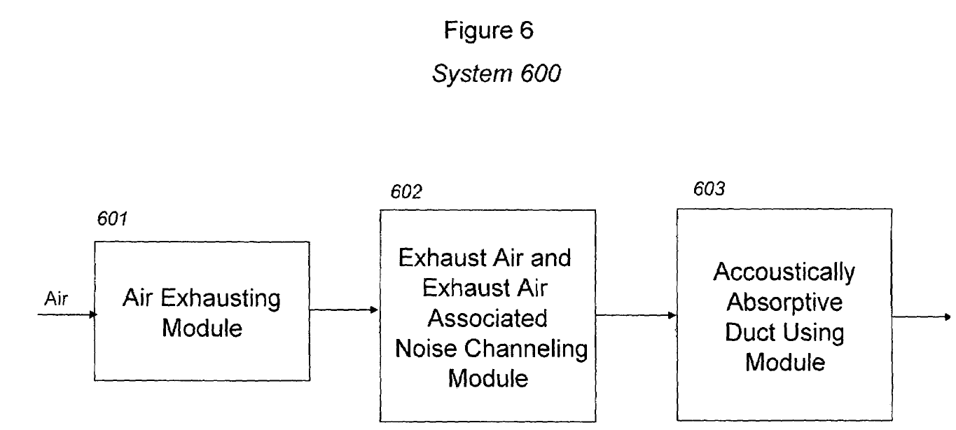

FIG. 6 illustrates an exemplary embodiment of a system 600 of exhaust air and reducing exhaust-air associated noise from a computer rack of the present invention. According to FIG. 6, the system 600 includes an air exhausting module (601) for exhausting the exhaust air from a rear-mounted blower directly through a side opening at a rear portion of the computer rack, an exhaust air and exhaust air associated noise channeling module (602) for channeling the exhaust air and the exhaust-air associated noise through an acoustically absorptive side chamber, the acoustically absorptive side chamber sealed to the side opening of the computer rack such that the exhaust air and the exhaust-air associated noise is ducted through the acoustically absorptive side chamber and exits the acoustically absorptive side chamber at an upper portion of the acoustically absorptive side chamber in a vertical direction towards a ceiling of a data center in which the computer rack is installed, and an acoustically absorptive duct using module (603) for using an acoustically absorptive duct of the acoustically absorptive side chamber to significantly attenuate the exhaust-air associated noise prior to radiating the exhaust-air associated noise from the upper portion of the acoustically absorptive side chamber.

While the invention has been described in terms of several exemplary embodiments, those skilled in the art will recognize that the invention can be practiced with modification within the spirit and scope of the appended claims. Further, it is noted that Applicant's intent is to encompass equivalents of all claim elements, even if amended later during prosecution.

What is claimed is:

1. A method of exhausting exhaust air and reducing exhaust-air associated noise from a computer rack, comprising:
exhausting said exhaust air and said exhaust-air associated noise from a rear-mounted blower directly through a side opening at a rear portion of said computer rack;
channeling said exhaust air and said exhaust-air associated noise through an acoustically absorptive side chamber, said acoustically absorptive side chamber sealed to said side opening of said computer rack such that said exhaust air and said exhaust-air associated noise is ducted through said acoustically absorptive side chamber and exits said acoustically absorptive side chamber at an upper portion of said acoustically absorptive side chamber in a vertical direction towards a ceiling of a data center in which said computer rack is installed; and
using an acoustically absorptive duct of said acoustically absorptive side chamber to significantly attenuate said exhaust-air associated noise prior to radiating said exhaust-air associated noise from said upper portion of said acoustically absorptive side chamber,
wherein said exhaust air and said exhaust-air associated noise are prevented from exhausting directly through said rear portion of said computer rack,
wherein said rear portion of said computer rack comprises a decorative rear door designed to have a minimal impact on floor space and aisle space of said data center, said decorative rear door being able to be opened without said exhaust air and exhaust-air associated noise escaping through said rear portion of said computer rack, said decorative rear door comprising an inexpensive, thin, and lightweight material,
wherein said exhaust air exits vertically from said upper portion of said acoustically absorptive side chamber with sufficient momentum such that a plurality of computer racks of said data center are unable to intake said exhaust air, and
wherein said upper portion of said acoustically absorptive side chamber comprises an air exhaust opening, said air exhaust opening having a height substantially similar to that of a top of said computer rack.
